(19) United States
(12) Patent Application Publication
(10) Pub. No.: US 2015/0189751 A1
(43) Pub. Date: Jul. 2, 2015

(54) WIRING BOARD, METHOD FOR FABRICATING THE SAME, AND ELECTRONIC APPARATUS

(71) Applicant: FUJITSU LIMITED, Kawasaki-shi (JP)

(72) Inventors: Tomoyuki AKAHOSHI, Atsugi (JP); Daisuke Mizutani, Sagamihara (JP); Motoaki Tani, Akashi (JP)

(73) Assignee: FUJITSU LIMITED, Kawasaki-shi (JP)

(21) Appl. No.: 14/564,251

(22) Filed: Dec. 9, 2014

(30) Foreign Application Priority Data
Dec. 26, 2013 (JP) 2013-268591

(51) Int. Cl. H05K 1/11; H05K 3/00; H05K 3/46

(52) U.S. Cl. CPC H05K 1/115; H05K 3/46; H05K 3/0091

(57) ABSTRACT

A wiring board includes a conductor formed on an inner wall of a through hole made in a core board, resin formed inside the conductor in the through hole, and, for example, a land formed over the conductor and the resin. Vias are formed over the land. The vias are connected to a plurality of connection regions of the land extending over the conductor and the resin in the through hole. The land is held by the vias connected to the plurality of connection regions. This controls the thermal expansion of the resin to a land side and therefore prevents a fracture of the land.

### CROSS-REFERENCE TO RELATED APPLICATION

This application is based upon and claims the benefit of priority of the prior Japanese Patent Application No. 2013-268591, filed on Dec. 26, 2013, the entire contents of which are incorporated herein by reference.

### FIELD

The embodiment discussed herein is related to a wiring board, a wiring board fabrication method and an electronic apparatus.

### BACKGROUND

A wiring board including conductor portions (referred to as through holes, vias, or the like) which pierce an insulating portion, such as a determined layer or a board, and which connect conductors, such as wirings or vias, formed with the insulating portion between is known as one of wiring boards.

A form in which a conductor is formed by a plating method or the like on the inner wall of a through hole that pierces an insulating portion is known as such a conductor portion. Furthermore, in reference to a conductor portion in such a form, the technique of filling the inside of a conductor formed on the inner wall of a through hole with resin, the technique of forming another conductor (referred to as a land, a wiring, or lid plating) so as to cover a conductor formed on the inner wall of a through hole and resin with which the inside of the conductor is filled, and the like are known.

Japanese Laid-open Patent Publication No. 2002-290031

Japanese Laid-open Patent Publication No. 2002-305377

Japanese Laid-open Patent Publication No. 2001-244635

With a wiring board having a structure in which a conductor is formed on the inner wall of a through hole in an insulating portion and in which the inside of the conductor is filled with resin, there are differences in thermal expansivity among used materials, that is to say, an insulating material, a conductor material, and a resin material. Resin thermally expands to a comparatively great degree and then contracts by cooling. Therefore, if a second conductor is formed over a conductor formed on the inner wall of a through hole in an insulating portion and resin with which the inside of the conductor is filled, then a fracture may occur in the second conductor due to the expansion and contraction of the resin in the through hole.

### SUMMARY

According to an aspect, there is provided a wiring board including a first insulating portion, a first through hole made in the first insulating portion, a first conductor portion formed on an inner wall of the first through hole, a first resin portion formed inside the first conductor portion in the first through hole, a second conductor portion formed over the first conductor portion and the first resin portion, a second insulating portion formed over the second conductor portion, and a third conductor portion formed in the second insulating portion and connected to a plurality of first regions of the second conductor portion extending over the first conductor portion and the first resin portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of a wiring board;

FIGS. 2A and 2B illustrate an example of a wiring board in another form;

FIG. 3 illustrates an example of a wiring board in still another form;

FIGS. 4A, 4B, and 4C are views for describing a first process for fabricating a wiring board;

FIGS. 5A and 5B are views for describing a second process for fabricating the wiring board;

FIGS. 6A and 6B are views for describing a third process for fabricating the wiring board;

FIGS. 7A and 7B are views for describing a fourth process for fabricating the wiring board;

FIGS. 8A and 8B are views for describing a fifth process for fabricating the wiring board;

FIGS. 9A and 9B are views for describing a sixth process for fabricating the wiring board;

FIG. 10 is a view for describing a through hole making step using a laser irradiation apparatus;

FIG. 11 indicates an example of the flow of through hole making with the laser irradiation apparatus (part 1);

FIG. 12 indicates an example of the flow of through hole making with the laser irradiation apparatus (part 2);

FIGS. 13A, 13B, 13C, and 13D illustrate examples of the arrangement of vias;

FIG. 14 illustrates an example of the arrangement of vias over different lands (part 1);

FIGS. 15A and 15B illustrate examples of the arrangement of vias over different lands (part 2);

FIG. 16 illustrates an example of the arrangement of vias over different lands (part 3);

FIGS. 17A, 17B, and 17C illustrate an example of the arrangement of vias in upper and lower layers (part 1);

FIGS. 18A, 18B, and 18C illustrate an example of the arrangement of vias in upper and lower layers (part 2);

FIG. 19 illustrates another example of a wiring board;

FIG. 20 illustrates an example of an electronic apparatus; and

FIG. 21 illustrates another example of an electronic apparatus.

### DESCRIPTION OF EMBODIMENTS

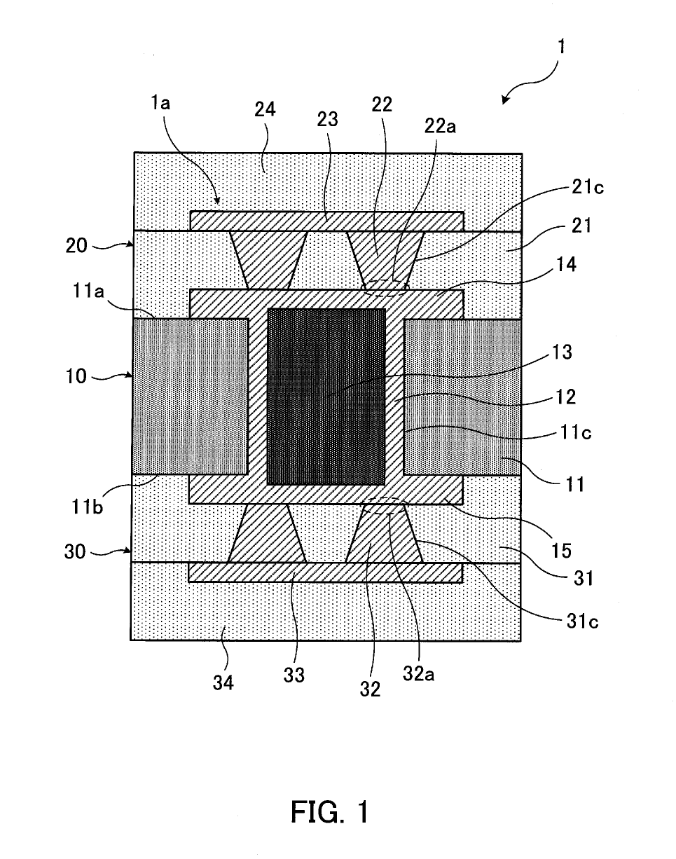

FIG. 1 illustrates an example of a wiring board. FIG. 1 is a fragmentary schematic sectional view of an example of a wiring board.

FIG. 1 illustrates as a wiring board 1 a buildup board having a via connection structure 1a in which conductors in upper and lower layers are connected by vias. The wiring board 1 illustrated in FIG. 1 includes a core layer 10 and buildup layers 20 and 30 formed over both principal planes (upper and lower surfaces) of the core layer 10.

The core layer 10 includes a core board 11, a conductor (via) 12, resin 13, and lands 14 and 15.

An organic insulating board, such as a glass epoxy board, a polyimide board, or a bismaleimide-triazine board, or an inorganic insulating board, such as a ceramic board, is used as the core board 11. A through hole 11c which penetrates an upper surface 11a and a lower surface 11b of the core board 11 is made in the core board 11.

The conductor 12 of determined thickness is formed on an inner wall of the through hole 11c in the core board 11. Continuity between an upper surface 11a side and a lower surface 11b side of the core board 11 is realized by the conductor 12. The conductor 12 functions as a via which electrically connects conductors (land 14 or the like and the land 15 or the like) formed over and under the core board 11. Various conductor materials are used for forming the conductor 12. For example, copper (Cu) is used for forming the conductor 12. Furthermore, a conductor material, such as silver (Ag), gold (Au), or aluminum (Al), is used in place of copper for forming the conductor 12.

A region inside the conductor 12 formed on the inner wall of the through hole 11c is filled with the resin 13. A resin material, such as epoxy resin, is used as the resin 13.

The land 14 is formed on the upper surface 11a side of the core board 11. The land 14 is formed over the resin 13 and the conductor 12 in the through hole 11c and the core board 11 around the through hole 11c.

The land 15 is formed on the lower surface 11b side of the core board 11. The land 15 is formed under the resin 13 and the conductor 12 in the through hole 11c and the core board 11 around the through hole 11c.

The lands 14 and 15 cover the resin 13 and the conductor 12 in the through hole 11c and are electrically connected to the conductor 12. Various conductor materials are used for forming the lands 14 and 15. For example, copper is used for forming the lands 14 and 15.

For example, each of the lands 14 and 15 has an isolated island-like pattern having a round shape or the like from above. Alternatively, the land 14 or 15 may be a part of a wiring with a determined pattern formed over the upper surface 11a of the core board 11 or under the lower surface 11b of the core board 11.

The buildup layer 20 formed on an upper surface side of the core layer 10 (upper surface 11a side of the core board 11) includes an insulating layer 21, a plurality of vias 22, and a land 23.

The insulating layer 21 is formed over the upper surface 11a of the core board 11 so as to cover the land 14. For example, a resin material (prepreg), such as epoxy resin, phenolic resin, or polyimide resin, which contains glass filler, glass fiber, carbon fiber, or the like is used for forming the insulating layer 21.

Each of the plurality of vias 22 is formed in a through hole 21c in the insulating layer 21 and is connected to the land 14 which covers the conductor 12 and the resin 13 in the through hole 11c in the core board 11. Each via 22 is formed so that its connection region 22a at which it is connected to the land 14 will be over a region of the land 14 extending over the conductor 12 and the resin 13 in the through hole 11c (region including the boundary between the conductor 12 and the resin 13). Each via 22 is electrically connected to the land 14.

The land 23 is formed over the insulating layer so as to cover the plurality of vias 22, and is electrically connected to the plurality of vias 22. For example, the land 23 has an isolated island-like pattern having a round shape or the like from above. Alternatively, the land 23 may be a part of a wiring with a determined pattern formed over the insulating layer 21.

An insulating layer 24 is formed over the insulating layer 21. For example, prepreg is used for forming the insulating layer 24. This is the same with the insulating layer 21. A via, a land, a wiring, or the like (not illustrated in FIG. 1) may be formed in the insulating layer 24.

The buildup layer 30 formed under a lower surface side of the core layer 10 (lower surface 11b side of the core board 11) also includes an insulating layer 31, a plurality of vias 32, and a land 33.

The insulating layer 31 is formed under the lower surface 11b of the core board 11 so as to cover the land 15. For example, prepreg is used for forming the insulating layer 31.

Each of the plurality of vias 32 is formed in a through hole 31c in the insulating layer 31 and is connected to the land 15 which covers the conductor 12 and the resin 13 in the through hole 11c in the core board 11. Each via 32 is formed so that its connection region 32a at which it is connected to the land 15 will be over a region of the land 15 extending over the conductor 12 and the resin 13 in the through hole 11c (region including the boundary between the conductor 12 and the resin 13). Each via 32 is electrically connected to the land 15.

The land 33 is formed under the insulating layer 31 so as to cover the plurality of vias 32, and is electrically connected to the plurality of vias 32. For example, the land 33 has an isolated island-like pattern having a round shape or the like from above. Alternatively, the land 33 may be a part of a wiring with a determined pattern formed under the insulating layer 31.

An insulating layer 34 is formed under the insulating layer 31. For example, prepreg is used for forming the insulating layer 34. A via, a land, a wiring, or the like (not illustrated in FIG. 1) may be formed in the insulating layer 34.

FIG. 1 illustrates one via connection structure 1a. However, the wiring board 1 may include a plurality of via connection structures 1a.

For example, the via connection structure 1a included in the wiring board 1 is used for supplying a power supply to an electronic part mounted on the wiring board 1 or connecting an electronic part mounted on the wiring board 1 to ground (GND).

As stated above, with the via connection structure 1a included in the wiring board 1, the plurality of vias 22 are connected to the land 14 on the upper surface 11a side. The connection region 22a of each via 22 at which it is connected to the land 14 is over a region of the land 14 extending over the conductor 12 and the resin 13 in the through hole 11c. The plurality of vias 32 are connected to the land 15 on the lower surface 11b side. The connection region 32a of each via 32 at which it is connected to the land 15 is over a region of the land 15 extending over the conductor 12 and the resin 13 in the through hole 11c.

Even if the thermal expansivity of the resin 13 is higher than that of the core board 11, the conductor 12, and the lands 14 and 15 in the wiring board 1, the expansion of the resin 13 at heating time is controlled by the via connection structure 1a. That is to say, the wiring board 1 has a structure in which a region of the land 14 extending over the conductor 12 and the resin 13 in the through hole 11c is held by the plurality of vias 22 and in which a region of the land 15 extending under the conductor 12 and the resin 13 in the through hole 11c is held by the plurality of vias 32. As a result, the thermal expansion of the resin 13 to a land 14 side and a land 15 side is controlled.

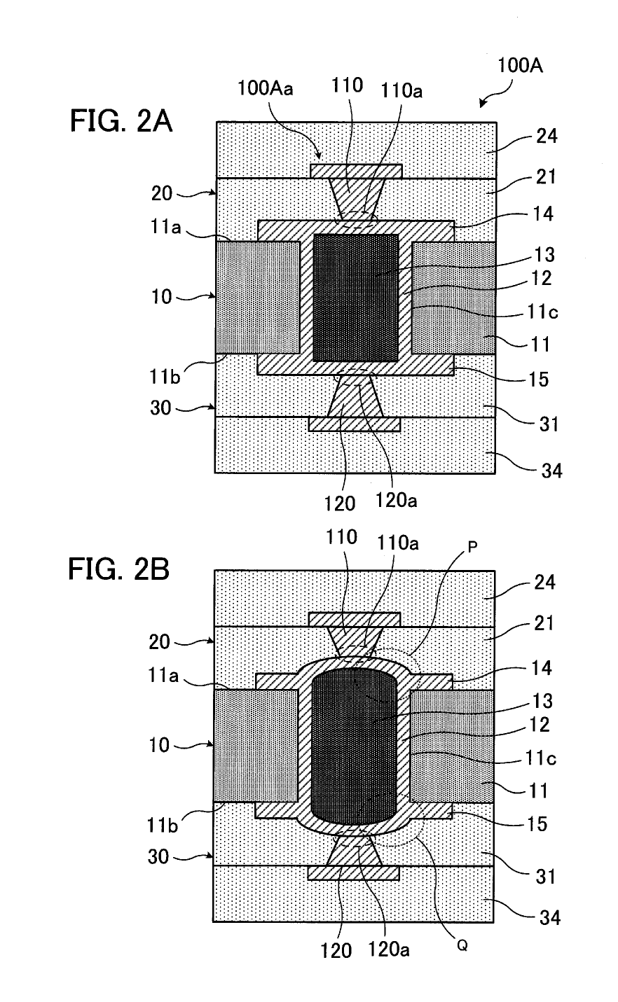

A wiring board having a via connection structure in another form will now be described for comparison. FIGS. 2A and 2B illustrate an example of a wiring board in another form. FIGS. 2A and 2B are fragmentary schematic sectional views of an example of a wiring board in another form. FIG. 2A illustrates an example of a state before heating and FIG. 2B illustrates an example of a state after heating.

As illustrated in FIG. 2A, a wiring board 100A differs from the above wiring board 1 in that it has a via connection structure 100Aa in which a single via 110 is connected to a land 14 of a core layer 10 and in which a single via 120 is connected to a land 15 of the core layer 10.

With the wiring board 100A, the via 110 is connected to the land 14 at a position over a central portion of resin 13 and the via 120 is connected to the land 15 at a position under the central portion of the resin 13.

As illustrated in FIG. 2A, for example, the via 110 is formed so that the plane size of a connection region 110a which connects the via 110 and the land 14 will be smaller than that of a through hole 11c in a core board 11 (resin 13 with which the through hole 11c is filled). As illustrated in FIG. 2A, for example, the via 120 is formed so that the plane size of a connection region 120a which connects the via 120 and the land 15 will be smaller than that of the through hole 11c in the core board 11 (resin 13 with which the through hole 11c is filled). If the plane size of the via 110 (connection region 110a) and the via 120 (connection region 120a) is approximately the same as that of the through hole 11c in the core board 11, it takes a long time to form the vias 110 and 120 by, for example, the plating method or a void may appear inside the via 110 or 120.

As illustrated in FIG. 2B, for example, if the thermal expansivity of the resin 13 with which the through hole 11c in the core board 11 is filled is higher than that of the core board 11, and the like in the wiring board 100A, the resin 13 may thermally expand to a land 14 side and a land 15 side at the time of the wiring board 100A being heated.

Such thermal expansion may cause a fracture in a portion P of the land 14 between the connection region 110a which connects the via 110 and the land 14 and a conductor 12 formed on an inner wall of the through hole 11c or in a portion Q of the land 15 between the connection region 120a which connects the via 120 and the land 15 and the conductor 12 formed on the inner wall of the through hole 11c. That is to say, the resin 13 expands by heating and then contracts by cooling. However, the lands 14 and 15 deformed with the expansion of the resin 13 at heating time cannot follow the contraction of the resin 13 at cooling time as a whole. As a result, the portion P of the land 14 or the portion Q of the land 15 may fracture.

If a fracture occurs in the portion P of the land 14 or the portion Q of the land 15, then continuity between the via 110 on an upper surface 11a side of the core board 11 and the via 120 on a lower surface 11b side of the core board 11 via the conductor 12 formed on the inner wall of the through hole 11c may be lost or a resistance value between them may increase.

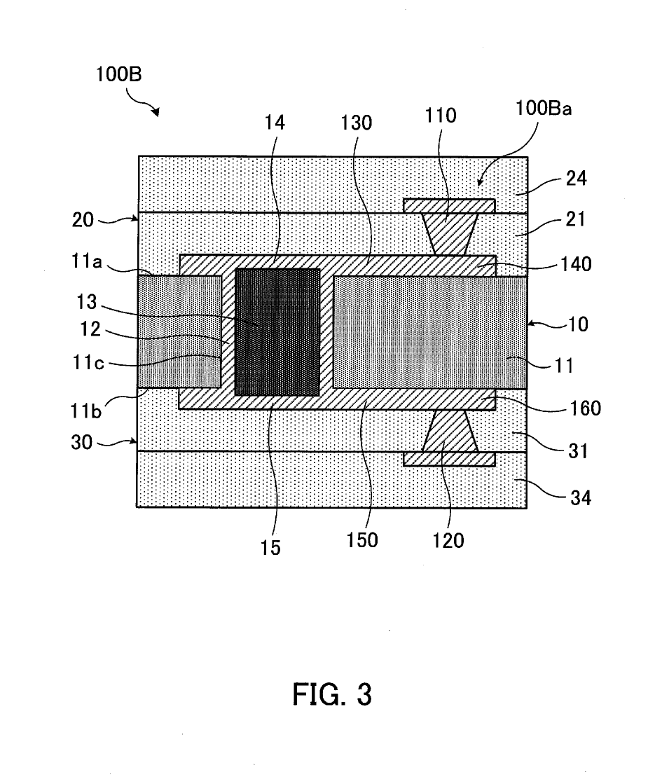

On the other hand, FIG. 3 illustrates an example of a wiring board in still another form. FIG. 3 is a fragmentary schematic sectional view of an example of a wiring board in still another form.

A wiring board 100B illustrated in FIG. 3 has a structure in which a via 110 is connected to a land 140 drawn out with a wiring 130 from a land 14 which covers resin 13 and in which a via 120 is connected to a land 160 drawn out with a wiring 150 from a land 15 which covers the resin 13. That is to say, with the wiring board 100B, the via 110 is formed above the land 14 at a position apart from over a central portion of the resin 13 and the via 120 is formed below the land 15 at a position apart from under the central portion of the resin 13. The wiring board 100B differs from the above wiring board 100A illustrated in FIGS. 2A and 2B in this respect.

If a structure, such as the wiring board 100B, is adopted, the lands 14 and 15 deformed with the expansion of the resin 13 at heating time cannot follow the contraction of the resin 13 at cooling time as a whole and a fracture may occur. This is the same with the above wiring board 100A. With the wiring board 100B, however, even if the land 14 or 15 which covers the resin 13 fractures, continuity via a conductor 12 (that is to say, via the land 140, the wiring 130, the conductor 12, the wiring 150, and the land 160) between the vias 110 and 120 formed over and under a core board 11 may be maintained.

However, the wiring board 100B includes the wiring 130 and the land 140 for drawing out the via 110 outside the resin 13 and the wiring 150 and the land 160 for drawing out the via 120 outside the resin 13. This may increase a resistance value between the via 110 and the conductor 12 or between the via 120 and the conductor 12. In addition, the vias 110 and 120 are drawn out outside the resin 13. Accordingly, the occupied area of a via connection structure 100Ba is large compared with a case where vias 110 and 120 are formed over and under resin 13. If a plurality of via connection structures 100Ba are included, then a pitch between them may increase and an inductance value may rise. That is to say, the electrical characteristics, such as a resistance value and an inductance value, of the wiring board 100B may be worse than those of the wiring board 100A in which the vias 110 and 120 are formed over and under the resin 13.

With the above wiring board 1 illustrated in FIG. 1, on the other hand, the plurality of vias 22 are connected to regions of the land 14 extending over the conductor 12 and the resin 13 and the plurality of vias 32 are connected to regions of the land 15 extending under the conductor 12 and the resin 13. The land 14 and the land 15 are held by the plurality of vias 22 and the plurality of vias 32 respectively.

With the wiring board 1, regions of the land 14 over the resin 13 in the through hole 11c are held by the plurality of vias 22 and regions of the land 15 under the resin 13 in the through hole 11c are held by the plurality of vias 32. As a result, the expansion of the resin 13 at heating time is controlled. This prevents the land 14 or 15 from fracturing. In addition, regions of the land 14 over the conductor 12 in the through hole 11c are held by the plurality of vias 22 and regions of the land 15 under the conductor 12 in the through hole 11c are held by the plurality of vias 32. This prevents a fracture from occurring at a portion between the land 14 or the land 15 and the conductor 12 (prevents the land 14 or the land 15 from separating from the conductor 12). By connecting the plurality of vias 22 to the regions of the land 14 extending over the conductor 12 and the resin 13 and connecting the plurality of vias 32 to the regions of the land 15 extending under the conductor 12 and the resin 13, the thermal expansion of the resin 13 is controlled and a fracture of the land 14 or the land 15 caused by the thermal expansion of the resin 13 is prevented.

Furthermore, the plurality of vias 22 are connected to the regions of the land 14 extending over the conductor 12 and the resin 13 and the plurality of vias 32 are connected to the regions of the land 15 extending under the conductor 12 and the resin 13, so the occupied area of the via connection structure 1a is small compared with a case where the lands 14 and 15 which cover the resin 13 are drawn out outside the resin 13 with the wirings or the like. As a result, if the wiring board 1 includes a plurality of via connection structures 1a, an increase in pitch is checked and a deterioration of electrical characteristics, such as a resistance value and an inductance value, is prevented. In addition, the occupied area of the via connection structure 1a is small. Therefore, the size of the wiring board 1 can be reduced or other wirings or the like can be arranged more flexibly.

By adopting the above via connection structure 1a, the wiring board 1 with high reliability is realized. In addition, the wiring board 1 in which the occupied area of the via connection structure 1a is small and which has good electrical characteristics is realized.

The via connection structure 1a in which the plurality of vias 22 are connected to the land 14 on the upper surface 11a side of the core board 11 and in which the plurality of vias 32 are connected to the land 15 on the lower surface 11b side of the core board 11 is taken as an example. In addition, if a via connection structure in which a land that covers resin 13 is not formed over or under the resin 13 is adopted, then a plurality of vias may be connected to a region extending over or under a conductor 12 and the resin 13 of only a land that covers the resin 13.

Furthermore, the above via connection structure 1a is adopted in the wiring board 1 and the resin 13 may contain insulating filler, such as silica (SiO₂) or glass, or conductive filler, such as metal. For example, the use of the resin 13 containing determined insulating filler makes it possible to control the thermal expansion of the resin 13, and the use of the resin 13 containing determined conductive filler makes it possible to make the resin 13 conductive.

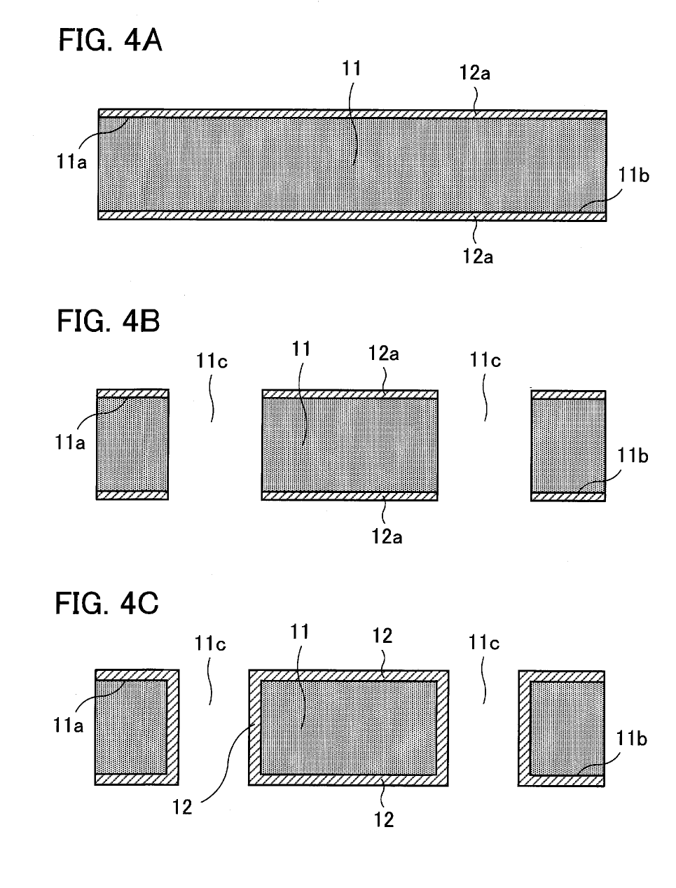

An example of a method for fabricating the wiring board 1 will now be described with reference to FIGS. 4A, 4B, and 4C through 9A and 9B and FIGS. 10 through 18A, 18B, and 18C.

FIGS. 4A, 4B, and 4C are views for describing a first process for fabricating the wiring board. FIG. 4A is a fragmentary schematic sectional view of an example of a board preparation step. FIG. 4B is a fragmentary schematic sectional view of an example of a through hole making step. FIG. 4C is a fragmentary schematic sectional view of an example of a conductor formation step.

As illustrated in FIG. 4A, first the core board 11 over the upper surface 11a and under the lower surface 11b of which a conductor 12a is formed is prepared. For example, a double-sided copper-clad board (copper-clad laminate) obtained by sticking copper foil as the conductor 12a over the upper surface 11a and under the lower surface 11b of the core board 11, such as a resin board or ceramic board, is prepared. For example, the core board 11 with a thickness of 0.4 to 0.8 mm over the upper surface 11a and under the lower surface 11b of which the conductor 12a with a thickness of 0.02 to 0.03 mm is formed is prepared.

As illustrated in FIG. 4B, through holes 11c are then made at (two, in this example) determined positions in the core board 11 over the upper surface 11a and under the lower surface 11b of which the conductor 12a is formed. For example, a drill whose diameter corresponds to the open size (diameter) of the through holes 11c to be made is used for drilling the core board 11 over the upper surface 11a and under the lower surface 11b of which the conductor 12a is formed. By doing so, the through holes 11c are made. For example, a drill having a determined diameter is used for making the through holes 11c having an open diameter of 0.15 to 0.25 mm.

For example when the drill is used for making the through holes 11c, the center of the drill is positioned on the basis of specifications for the wiring board 1 to be fabricated at the coordinates of the center of a region, in which each through hole 11c is to be made, of the core board 11 over the upper surface 11a and under the lower surface 11b of which the conductor 12a is formed. By doing so, the through holes 11c are made.

As illustrated in FIG. 4C, after the through holes 11c are made, the conductor 12 is formed on inner walls of the through holes 11c made in the core board 11. For example, an electroless plating method or the electroless plating method and an electrolytic plating method are used for forming the conductor 12 on the inner walls of the through holes 11c made in the core board 11. The conductor 12 is formed on the inner walls of the through holes 11c. In addition, the conductor 12 is formed over the conductor 12a over the upper surface 11a of the core board 11 and under the conductor 12a under the lower surface 11b of the core board 11 (FIGS. 4A and 4B). For convenience, FIG. 4C illustrates a conductor over the upper surface 11a of the core board 11 and a conductor under the lower surface 11b of the core board 11 as the conductor 12 having a single layer. For example, the conductor 12 is formed so that its thickness from the inner walls of the through holes 11c will be 0.015 to 0.030 mm.

By forming the conductor 12, a state in which there is continuity between the upper surface 11a side and the lower surface 11b side of the core board 11 is brought about.

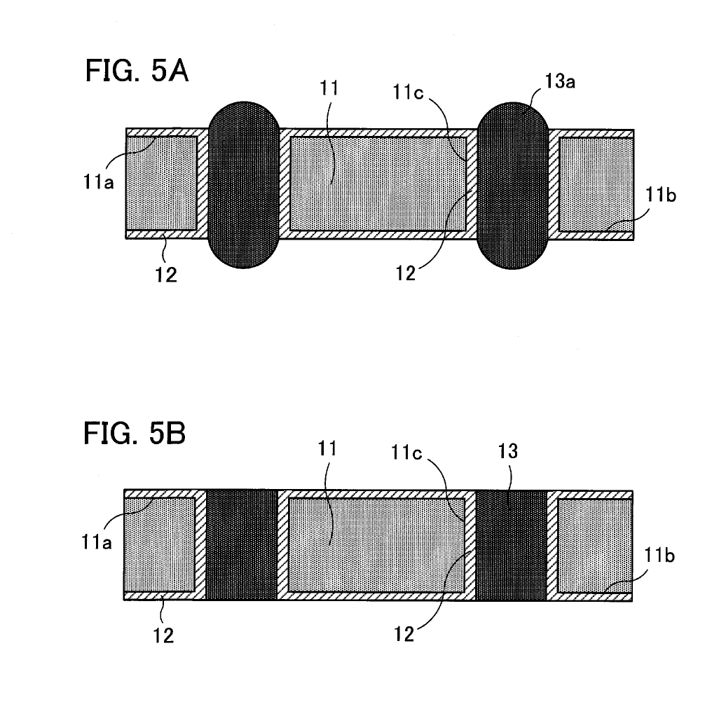

FIGS. 5A and 5B are views for describing a second process for fabricating the wiring board. FIG. 5A is a fragmentary schematic sectional view of an example of a resin formation step. FIG. 5B is a fragmentary schematic sectional view of an example of a polishing step.

As illustrated in FIG. 5A, after the conductor 12 is formed, resin 13a is formed in the through holes 11c on the inner walls of which the conductor 12 is formed. Thermosetting resin, thermoplastic resin, ultraviolet curing resin, or the like is used as the resin 13a. A method corresponding to the type of the resin 13a is used for causing the resin 13a to flow and supplying it into the through holes 11c. After that, the resin 13a supplied into the through holes 11c is cured by a method corresponding to the type of the resin 13a. As illustrated in FIG. 5A, the resin 13a formed in the through holes 11c at this point of time may protrude upward and downward from the through holes 11c.

FIG. 5A illustrates a case where the resin 13a is selectively formed in the through holes 11c. In addition, however, the resin 13a may be formed so as to cover the conductor 12 formed over the upper surface 11a of the core board 11 and under the lower surface 11b of the core board 11.

As illustrated in FIG. 5B, after the resin 13a is formed in the through holes 11c, the resin 13a (which includes, in the case of the resin 13a covering the conductor 12 formed over the upper surface 11a of the core board 11 and under the lower surface 11b of the core board 11, the resin 13a over the conductor 12) protruding upward and downward from the through holes 11c is removed and flattened. For example, polishing is performed along the conductor 12 formed over the upper surface 11a of the core board 11 and under the lower surface 11b of the core board 11 to remove unnecessary portions of the resin 13a.

By forming the resin 13a and removing its unnecessary portions, a state in which the through holes 11c in the core board 11 in which the conductor 12 is formed is filled with the resin 13 is brought about.

As described later, the method of setting regions of the insulating layer 21 in which the through holes 21c are to be made and regions of the insulating layer 31 in which the through holes 31c are to be made may be used on the basis of the thickness (measured value) of the conductor 12 actually formed on the inner walls of the through holes 11c in the core board 11. If this method is used, then the thickness of the conductor 12 actually formed on the inner walls of the through holes 11c is measured, for example, after the conductor 12 illustrated in FIG. 4C is formed, after the resin 13a illustrated in FIG. 5A is formed, or after the resin 13 illustrated in FIG. 5B is formed.

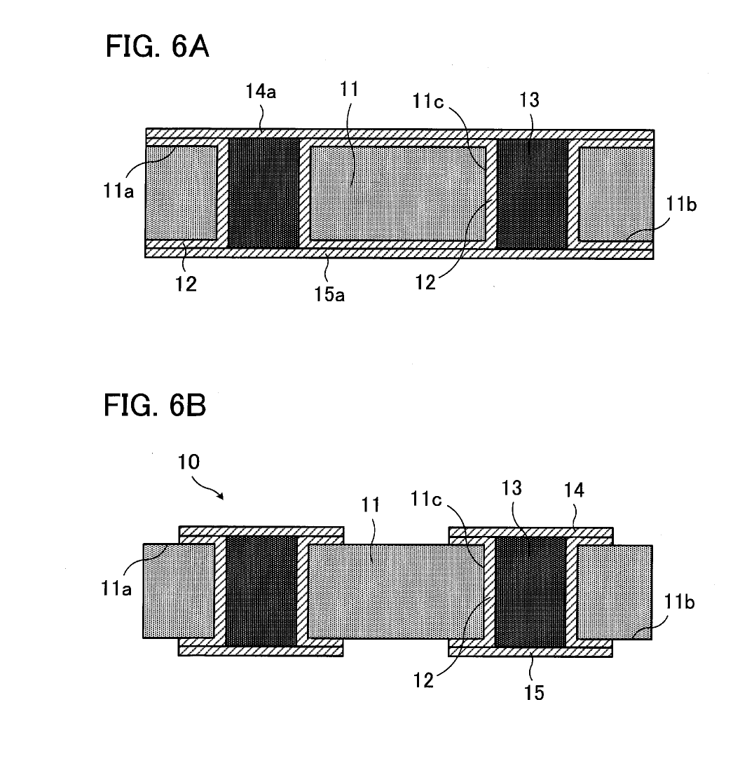

FIGS. 6A and 6B are views for describing a third process for fabricating the wiring board. FIG. 6A is a fragmentary schematic sectional view of an example of a conductor formation step. FIG. 6B is a fragmentary schematic sectional view of an example of a conductor patterning step.

As illustrated in FIG. 6A, after the resin 13 is formed, a conductor 14a is formed over the conductor 12 over the upper surface 11a of the core board 11 and a conductor 15a is formed under the conductor 12 under the lower surface 11b of the core board 11. For example, the electroless plating method or the electroless plating method and the electrolytic plating method are used for forming the conductor 14a over the conductor 12 over the upper surface 11a of the core board 11 and the conductor 15a under the conductor 12 under the lower surface 11b of the core board 11 (lid plating process). By forming the conductor 14a and the conductor 15a, the upper and lower ends of the resin 13 formed in the through holes 11c in the core board 11 are covered with the conductors 14a and 15a respectively.

As illustrated in FIG. 6B, after the conductor 14a and the conductor 15a are formed, patterning is performed on the conductor 12 and the conductor 14a over the upper surface 11a of the core board 11 and the conductor 12 and the conductor 15a under the lower surface 11b of the core board 11 to form determined shapes. For example, photolithography and etching are utilized for performing patterning. By performing patterning, the land 14 which covers the conductor 12 and the resin 13 in the through holes 11c and portions around the through holes 11c is formed on the upper surface 11a side and the land 15 which covers the conductor 12 and the resin 13 in the through holes 11c and portions around the through holes 11c is formed on the lower surface 11b side.

FIG. 6B illustrates the land 14 and the land 15 formed by performing patterning. By performing this patterning, however, a wiring having a determined shape and a land having a determined shape (not illustrated) may be formed over the core board 11. Furthermore, each of the land 14 and the land 15 may be formed as a part of a wiring (not illustrated).

By forming the land 14 and the land 15, the core layer 10 having a structure illustrated in FIG. 6B is obtained.

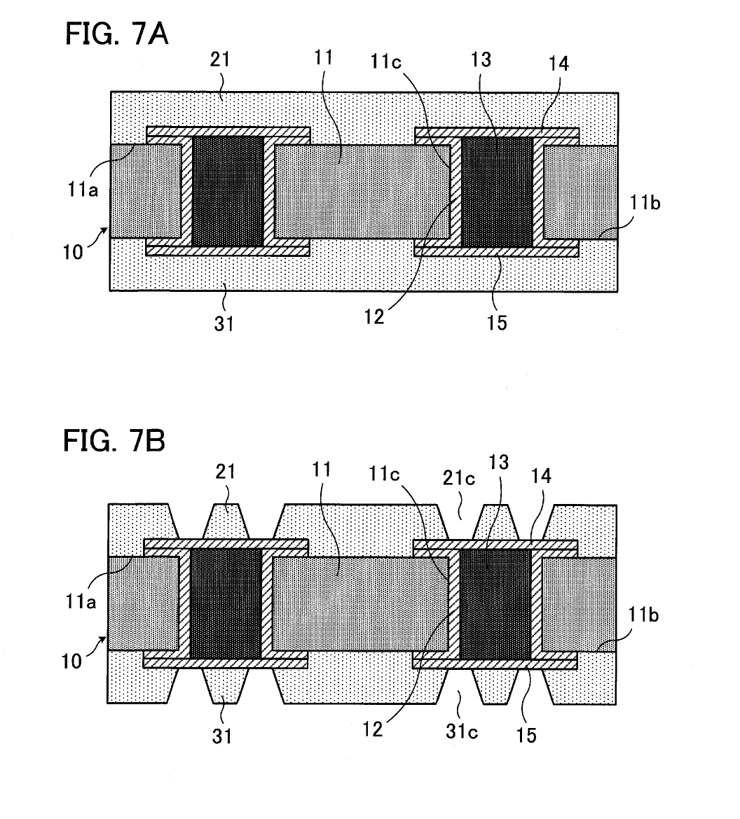

FIGS. 7A and 7B are views for describing a fourth process for fabricating the wiring board. FIG. 7A is a fragmentary schematic sectional view of an example of an insulating layer formation step. FIG. 7B is a fragmentary schematic sectional view of an example of a through hole making step.

After the core layer 10 is formed in the way illustrated in FIGS. 4A, 4B, and 4C through 6A and 6B, an insulating layer 21 and an insulating layer 31 each of which is a first layer are formed, as illustrated in FIG. 7A, on the upper surface 11a side and the lower surface 11b side, respectively, of the core board 11. For example, sheet-like prepreg used as the insulating layer 21 and the insulating layer 31 is prepared. The upper surface 11a and the lower surface 11b of the core board 11 over and under which the lands 14 and 15, respectively, and the like are formed in the above way are covered with the prepared prepreg. For example, at this time the core board 11 is covered with the prepared prepreg under vacuum and is then heat-treated.

The insulating layer 21 and the insulating layer 31 are formed in this way over the upper surface 11a and under the lower surface 11b, respectively, of the core board 11 over and under which the lands 14 and 15, respectively, and the like are formed.

As illustrated in FIG. 7B, after the insulating layer 21 and the insulating layer 31 are formed, a plurality of through holes 21c which lead to the lands 14 are made in the insulating layer 21 and a plurality of through holes 31c which lead to the lands 15 are made in the insulating layer 31. As illustrated in FIG. 7B, at this time a plurality of through holes 21c are made for one land 14 and a plurality of through holes 31c are made for one land 15. The plurality of through holes 21c are made so as to lead to a region of the land 14 extending over the conductor 12 and the resin 13 in the through hole 11c in the core board 11. The plurality of through holes 31c are made so as to lead to a region of the land 15 extending under the conductor 12 and the resin 13 in the through hole 11c in the core board 11.

In the example of FIG. 7B, two through holes 21c are made for one land 14 and two through holes 31c are made for one land 15. The details of the arrangement of the through holes 21c and the through holes 31c (arrangement of the vias 22 and the vias 32 formed in the through holes 21c and the through holes 31c respectively) will be described later.

The plurality of through holes 21c and the plurality of through holes 31c are made, for example, by irradiating the insulating layer 21 and the insulating layer 31 with a laser beam. A carbon dioxide gas laser, an excimer laser, a UV (Ultraviolet) laser, a YAG (Yttrium Aluminum Garnet) laser, or the like is used as a laser. A laser irradiation apparatus which emits a determined laser beam is used for making the plurality of through holes 21c at determined positions in the insulating layer 21 and making the plurality of through holes 31c at determined positions in the insulating layer 31. For example, the plurality of through holes 21c and the plurality of through holes 31c whose open diameters are 0.04 to 0.06 mm are made in the insulating layer 21 and the insulating layer 31 respectively.

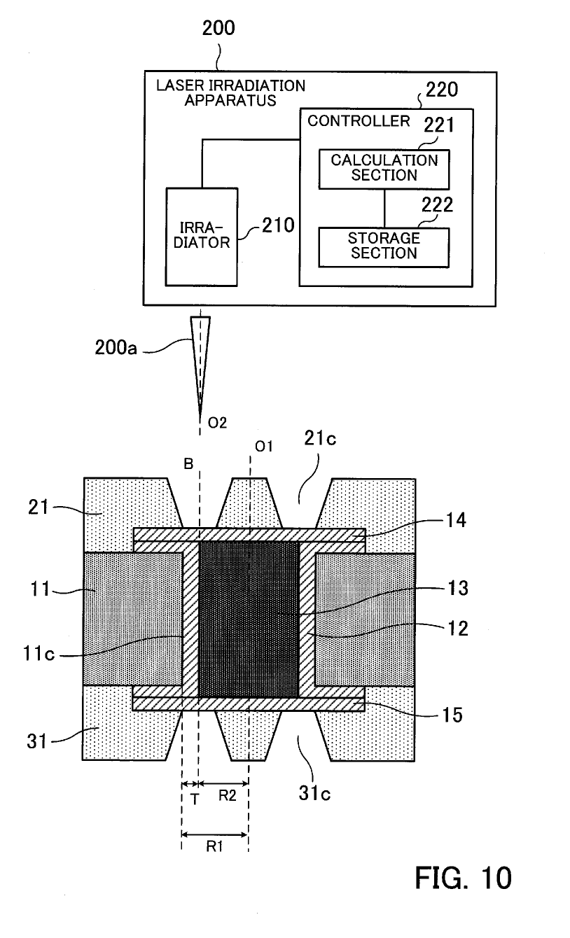

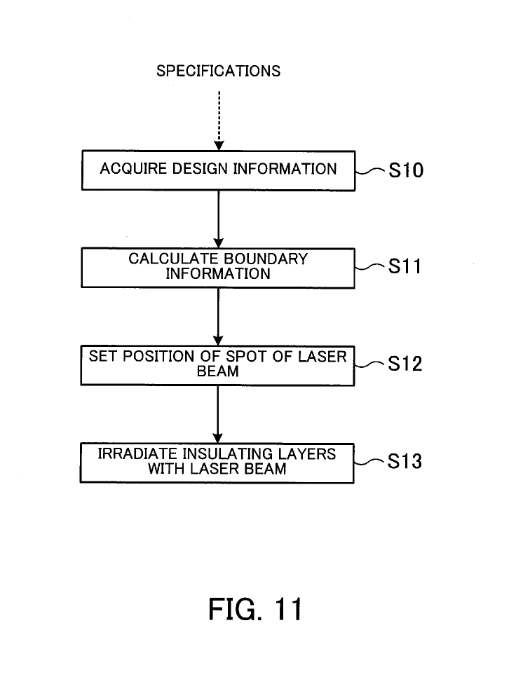

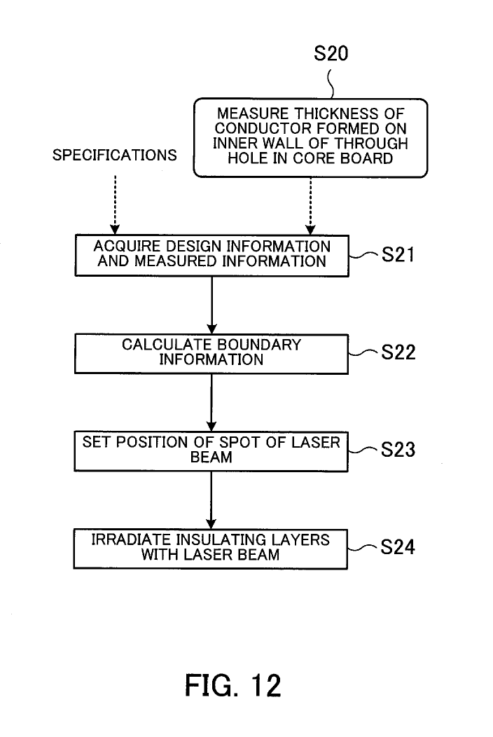

Through hole making with a laser irradiation apparatus will now be described with reference to FIGS. 10 through 12. FIG. 10 is a view for describing a through hole making step using a laser irradiation apparatus. FIGS. 11 and 12 indicate an example of the flow of through hole making with the laser irradiation apparatus.

As illustrated in FIG. 10, a laser irradiation apparatus 200 includes an irradiator 210 which emits a laser beam 200a and a controller 220 which controls the emission (position of a spot and the like) of the laser beam 200a from the irradiator 210. The controller 220 includes a calculation section 221 and a storage section 222. The calculation section 221 calculates the position of a spot of the laser beam 200a emitted from the irradiator 210 and the like. The storage section 222 stores various pieces of information used by the calculation section 221 for performing calculations and various pieces of information calculated by the calculation section 221. For example, the storage section 222 stores information such as the specifications for the wiring board 1, the coordinates of a center O1 and a radius R1 of a through hole 11c, a radius R2 of the resin 13, thickness T (design value or a measured value) of the conductor 12, the coordinates of a boundary B between the conductor 12 and the resin 13, a center O2 of a spot of the laser beam 200a, and the like. A computer including one or more processors, one or more memories, and the like is used as the controller 220.

A region (position of a spot of the laser beam 200a) in which each of the plurality of through holes 21c and the plurality of through holes 31c is to be made by the use of the laser irradiation apparatus 200 is set on the basis of the thickness T of the conductor 12 formed on the inner wall of the through hole 11c in the core board 11.

For example, on the basis of the specifications for the wiring board 1 to be fabricated, the laser irradiation apparatus 200 acquires information (design information) indicative of the coordinates of the center O1 and the radius R1 (or a diameter) of the through hole 11c and information (design information) indicative of the design value of the thickness T of the conductor 12 formed on the inner wall of the through hole 11c (step S10 of FIG. 11). The laser irradiation apparatus 200 may acquire the design value of the thickness T by calculating the differential between the radius R1 (or the diameter) of the through hole 11c and the radius R2 (or a diameter) of the resin 13 included in the specifications for the wiring board 1 to be fabricated or design information.

The laser irradiation apparatus 200 uses the acquired design information for calculating information (boundary information) indicative of the coordinates of the boundary B between the conductor 12 and the resin 13 in the through hole 11c (step S11 of FIG. 11).

The laser irradiation apparatus 200 uses the calculated boundary information indicative of the coordinates of the boundary B for setting the position of the spot of the laser beam 200a in a determined region including the boundary B (step S12 of FIG. 11). For example, the laser irradiation apparatus 200 sets the center O2 of the spot of the laser beam 200a over the boundary B.

On the basis of information indicative of the position of the spot set in this way, the laser irradiation apparatus 200 irradiates the insulating layer 21 and the insulating layer 31 with the laser beam 200a (step S13 of FIG. 11).

By adopting this method, the plurality of through holes 21c which lead to regions of the land 14 extending over the conductor 12 and the resin 13 in the through hole 11c in the core board 11 are made in the insulating layer 21 and the plurality of through holes 31c which lead to regions of the land 15 extending under the conductor 12 and the resin 13 in the through hole 11c in the core board 11 are made in the insulating layer 31.

In addition, the method of using a measured value of the thickness T of the conductor 12 may be adopted. In this case, first the thickness T of the conductor 12 actually formed on the inner wall of the through hole 11c is measured (step S20 of FIG. 12).

The actual thickness T of the conductor 12 is measured after the above step illustrated in FIG. 4C, FIG. 5A, or FIG. 5B (after the formation of the conductor 12 and before the formation of the conductor 14a and the conductor 15a). For example, the method of directly measuring the thickness T of the conductor 12 actually formed on the inner wall of the through hole 11c is used. Alternatively, the method of measuring the radius (or the diameter) of a cavity portion which remains in the through hole 11c after the actual formation of the conductor 12 or the radius R2 (or the diameter) of the resin 13 actually formed in the through hole 11c and indirectly measuring the thickness T of the conductor 12 from the differential between the radius (or the diameter) of the cavity portion or the radius R2 (or the diameter) of the resin 13 and the radius R1 (or the diameter) of the through hole 11c is used.

The laser irradiation apparatus 200 acquires information (design information) indicative of the coordinates of the center O1 and the radius R1 (or a diameter) of the through hole 11c on the basis of the specifications for the wiring board 1 to be fabricated and acquires information (actual measurement information) indicative of a measured value of the thickness T of the conductor 12 obtained in step S20 (step S21 of FIG. 12).

The laser irradiation apparatus 200 uses the acquired design information and measured information for calculating information (boundary information) indicative of the coordinates of the boundary B between the conductor 12 and the resin 13 in the through hole 11c (step S22 of FIG. 12).

The laser irradiation apparatus 200 uses the calculated boundary information indicative of the coordinates of the boundary B for setting the position of the spot of the laser beam 200a in a determined region including the boundary B (step S23 of FIG. 12). For example, the laser irradiation apparatus 200 sets the center O2 of the spot of the laser beam 200a over the boundary B.

On the basis of information indicative of the position of the spot set in this way, the laser irradiation apparatus 200 irradiates the insulating layer 21 and the insulating layer 31 with the laser beam 200a (step S24 of FIG. 12).

By adopting this method, the plurality of through holes 21c which lead to regions of the land 14 extending over the conductor 12 and the resin 13 in the through hole 11c in the core board 11 are also made in the insulating layer 21 and the plurality of through holes 31c which lead to regions of the land 15 extending under the conductor 12 and the resin 13 in the through hole 11c in the core board 11 are also made in the insulating layer 31.

In the above methods, the laser irradiation apparatus 200 acquires the design information indicative of the coordinates of the center O1 and the radius R1 (or the diameter) of the through hole 11c in the core board 11 on the basis of the specifications for the wiring board 1 to be fabricated. Furthermore, the following method may be used. After the formation of the through hole 11c in the core board 11, the center O1, the radius R1 (or the diameter), and the like of the through hole 11c actually formed are measured. Measured value are used for setting the position of the spot of the laser beam 200a.

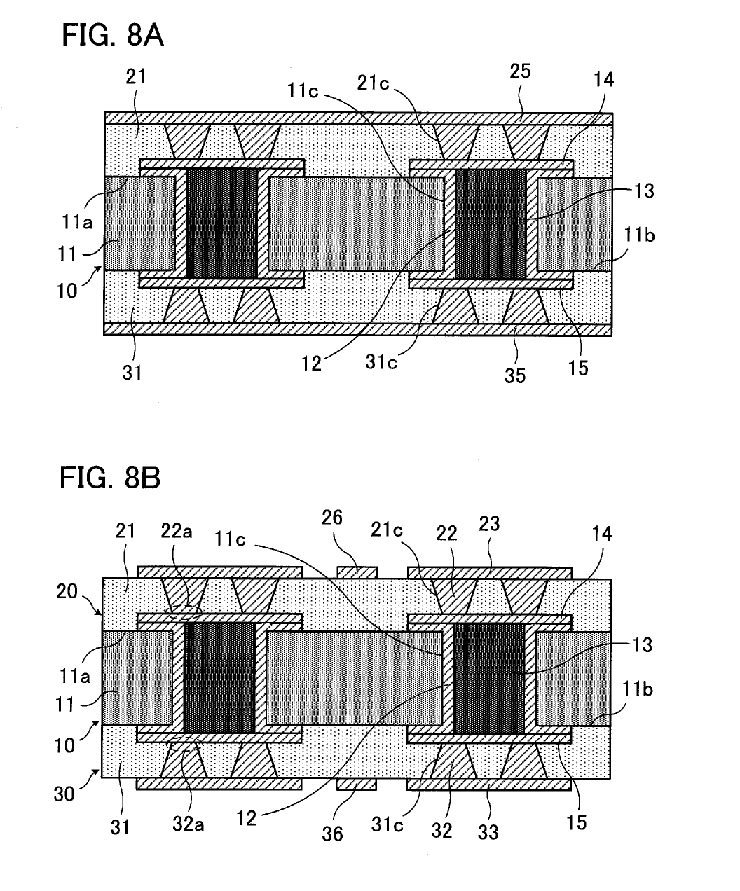

FIGS. 8A and 8B are views for describing a fifth process for fabricating the wiring board. FIG. 8A is a fragmentary schematic sectional view of an example of a conductor formation step. FIG. 8B is a fragmentary schematic sectional view of an example of a conductor patterning step.

As illustrated in FIG. 8A, after the plurality of through holes 21c and the plurality of through holes 31c are made in the insulating layer 21 and the insulating layer 31 respectively, a conductor 25 is formed in each through hole 21c and over the insulating layer 21 and a conductor 35 is formed in each through hole 31c and under the insulating layer 31. For example, the electrolytic plating method or the electroless plating method and the electrolytic plating method are used for forming the conductor 25 and the conductor 35.

The conductor 25 is formed in block in each through hole 21c and over the insulating layer 21. Alternatively, the conductor 25 is formed in each through hole 21c and is then formed over the insulating layer 21. The same applies to the conductor 35. That is to say, the conductor 35 is formed in block in each through hole 31c and under the insulating layer 31. Alternatively, the conductor 35 is formed in each through hole 31c and is then formed under the insulating layer 31.

As illustrated in FIG. 8B, after the conductor and the conductor 35 are formed, patterning is performed on the conductor 25 formed over the insulating layer 21 and the conductor 35 formed under the insulating layer 31 to form determined shapes.

By performing this patterning, the land 23 and a wiring 26 are formed over the insulating layer 21. The conductors 25 formed in the plurality of through holes 21c in the insulating layer 21 function as the vias 22 and the vias 22 connect the land 23 and the land 14. Similarly, by performing this patterning, the land 33 and a wiring 36 are formed under the insulating layer 31. The conductors 35 formed in the plurality of through holes 31c in the insulating layer 31 function as the vias 32 and the vias 32 connect the land 33 and the land 15.

As a result, the vias 22, the land 23, and the wiring 26 in a first layer of the buildup layer 20 and the vias 32, the land 33, and the wiring 36 in a first layer of the buildup layer 30 are formed.

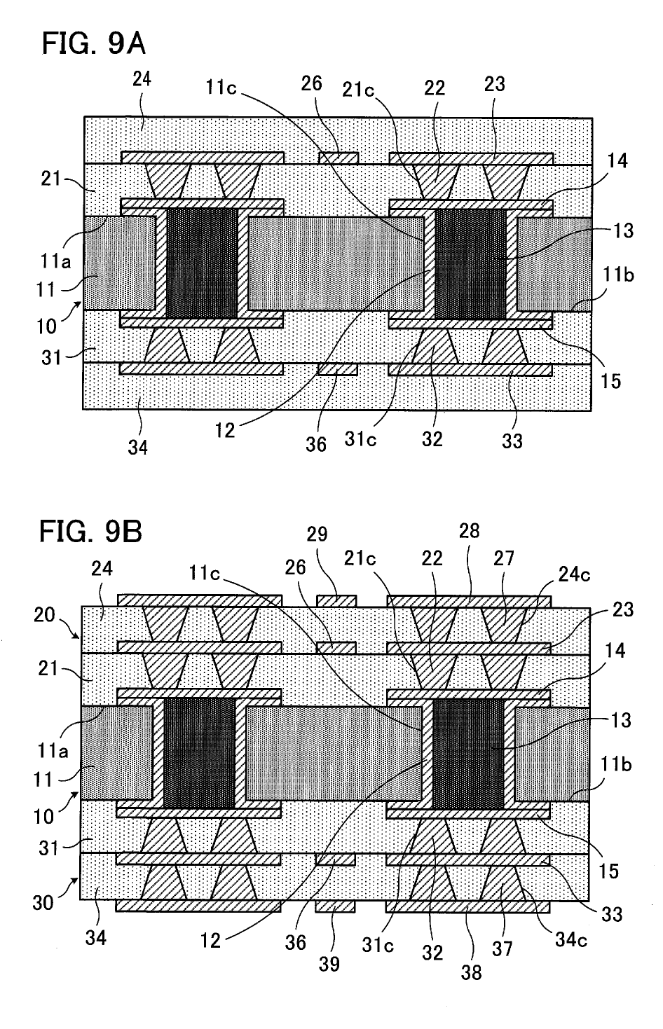

FIGS. 9A and 9B are views for describing a sixth process for fabricating the wiring board. FIG. 9A is a fragmentary schematic sectional view of an example of an insulating layer formation step. FIG. 9B is a fragmentary schematic sectional view of an example of a conductor pattern formation step.

After the vias 22, the land 23, and the wiring 26 and the vias 32, the land 33, and the wiring 36 are formed in the above way, the insulating layer 24 and the insulating layer 34 each of which is a second layer are formed, as illustrated in FIG. 9A, in the same way that is described in FIG. 7A.

The steps described in FIG. 7B, FIG. 8A, and FIG. 8B are then performed to obtain a structure illustrated in FIG. 9B. That is to say, a plurality of through holes 24c and a plurality of through holes 34c are made in the same way that is described in FIG. 7B. Conductors are formed in the same way that is described in FIG. 8A and patterning is performed in the same way that is described in FIG. 8B. The plurality of through holes 24c and the plurality of through holes 34c are made by the processes indicated in FIGS. 10 through 12.

As a result, vias 27, a land 28, and a wiring 29 in a second layer of the buildup layer 20 and vias 37, a land 38, and a wiring 39 in a second layer of the buildup layer 30 are formed.

The vias 27 formed in the plurality of through holes 24c connect the land 28 and the land 23. The vias 37 formed in the plurality of through holes 34c connect the land 38 and the land 33. The arrangement of the through holes 24c and the through holes 34c and the arrangement of the vias 27 and the vias 37 formed in the through holes 24c and the through holes 34c, respectively, will be described later in detail.

For example, the steps illustrated in FIGS. 9A and 9B are repeated a determined number of times to obtain the wiring board 1 which has the buildup layer 20 and the buildup layer 30 each including the determined number of laminated layers each including a determined conductor pattern.

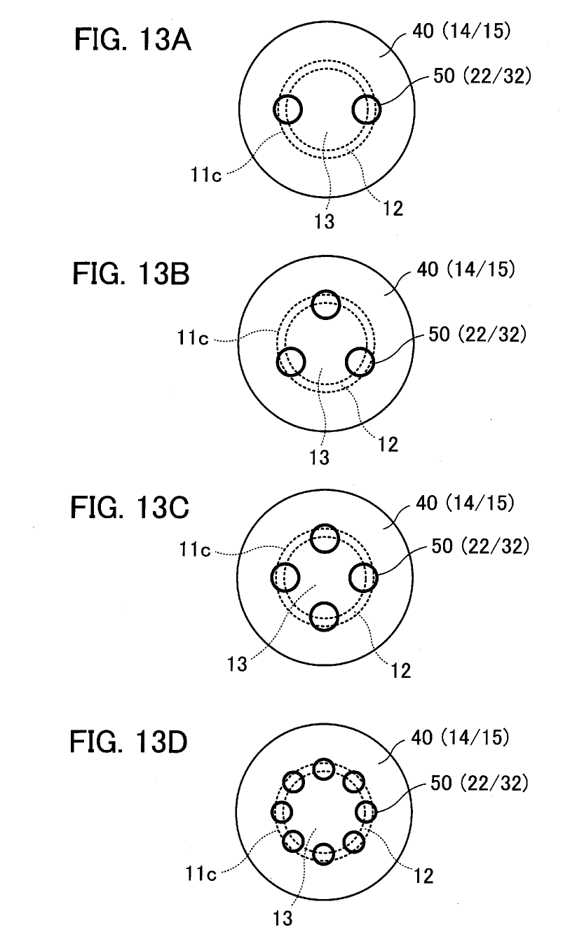

In the processes for fabricating the wiring board 1 described above, the plurality of vias 22 in the first layer connected to the land 14 of the core layer 10 and the plurality of vias 32 in the first layer connected to the land 15 of the core layer 10 are arranged, for example, in a way illustrated in FIG. 13A, 13B, 13C, or 13D.

FIGS. 13A, 13B, 13C, and 13D illustrate examples of the arrangement of vias. Each of FIGS. 13A, 13B, 13C, and 13D is a schematic plan view of the arrangement of vias over a land from a via side.

For convenience, a land 40 illustrated in FIGS. 13A through 13D corresponds to the above land 14 or land and vias 50 illustrated in FIGS. 13A through 13D correspond to the above vias 22 or vias 32. The conductor 12 formed on the inner wall of the through hole 11c in the core board 11 and the resin 13 formed inside the conductor 12 are under the land 40.

In the example of FIG. 13A, the vias 50 (corresponding to the vias 22 or the vias 32) connected to the land 40 (corresponding to the land 14 or the land 15) are arranged so that they will be over two regions of the land 40 extending over the conductor 12 and the resin 13 which are under the land 40. If the vias 50 are arranged over the two regions, it is desirable to arrange the two vias 50 at positions which are the farthest from each other (at constant intervals). By arranging the two vias 50 in this way, the land 40 is uniformly held by them and the thermal expansion of the resin 13 in the through hole 11c is controlled.

In the examples of FIGS. 13B, 13C, and 13D, the vias 50 are arranged over three, four, and eight regions, respectively, of the land 40 extending over the conductor 12 and the resin 13 which are under the land 40. The vias 50 may be arranged in this way over three or more regions of the land 40 extending over the conductor 12 and the resin 13 in the through hole 11c. If the vias 50 are arranged over three or more regions, it is desirable to arrange adjacent vias 50 at positions which are the farthest from each other (at constant intervals). By arranging the three or more vias 50 in this way, the land 40 is uniformly held by them and the thermal expansion of the resin 13 in the through hole 11c is controlled.

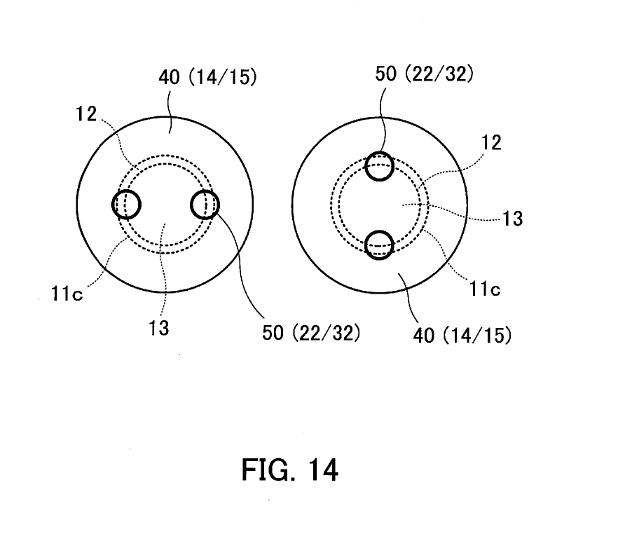

Furthermore, the vias 50 are arranged over lands formed in different regions in the same layer, for example, in ways illustrated in FIGS. 14 through 16.

FIGS. 14 through 16 illustrate examples of the arrangement of vias over different lands. Each of FIGS. 14 through 16 is a schematic plan view from a via side of the arrangement of vias over lands formed in different regions in the same layer.

As illustrated in FIG. 14, lands 40 (corresponding to the land 14 or the land 15) may be formed in different regions in the same layer in the wiring board 1. If a plurality of vias 50 (corresponding to the vias 22 or the vias 32) are arranged in this way over each of the lands 40 formed in the different regions, different arrangements of vias 50 may be adopted over adjacent lands 40.

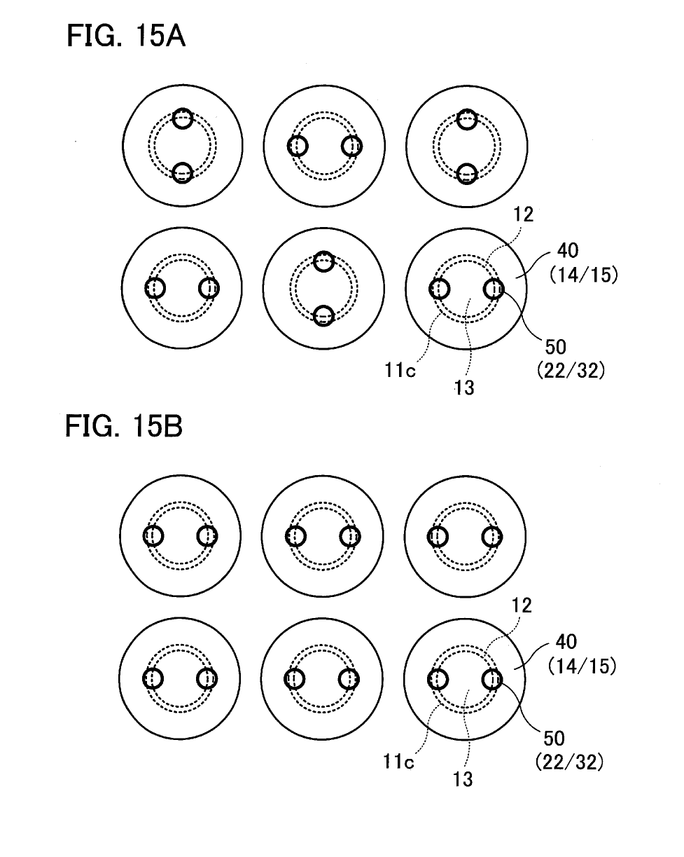

As illustrated in FIG. 14, for example, it is assumed that two vias 50 are arranged over one land 40. Two vias 50 are arranged over determined regions of one land 40. Two vias 50 the arrangement of which is obtained by rotating the arrangement of the two vias 50 over the one land 40 by 90 degrees are formed over determined regions of the other land 40. By adopting these arrangements, the density of vias 50 arranged in a layer in the wiring board 1 is uniformized. That is to say, different arrangements of vias 50 are adopted over adjacent lands 40 in FIG. 14. By adopting this method in FIG. 15A, the density of vias 50 arranged in a layer in the wiring board 1 is uniform compared with the case of FIG. 15B where the same arrangement of vias 50 is adopted.

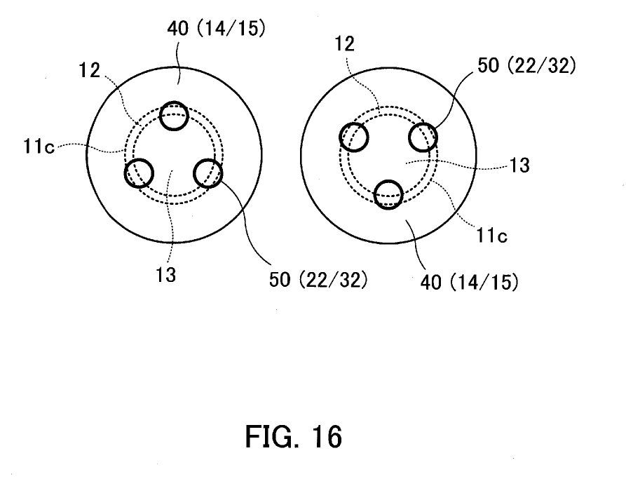

Furthermore, as illustrated in FIG. 16, it is assumed that three vias 50 are arranged over one land 40. Three vias 50 are arranged over determined regions of one land 40. Three vias 50 the arrangement of which is obtained by rotating the arrangement of the three vias 50 over the one land 40 by 60 degrees are formed over determined regions of the other land 40. By doing so, the density of vias 50 arranged in a layer in the wiring board 1 is uniformized.

These examples also apply to cases where four or more vias 50 are arranged over one land 40. Vias 50 the arrangement of which is obtained by rotating the arrangement of vias 50 over a land 40 by a determined angle are formed over an adjacent land 40. By doing so, the same effect that is described above is obtained.

In the above step described in FIG. 7B (and FIGS. 10 through 12), for example, the position of a spot of a laser beam is set on the basis of the arrangement of the vias 22 and 32 (vias 50) to be formed over the lands 14 and 15 (lands 40), respectively, in order to make the through holes 21c and the through holes 31c. In the steps described in FIGS. 8A and 8B, the conductors 25 and the conductors 35 are then formed in the made through holes 21c and through holes 31c respectively. By doing so, the vias 22 and the vias 32 in the first layers are formed.

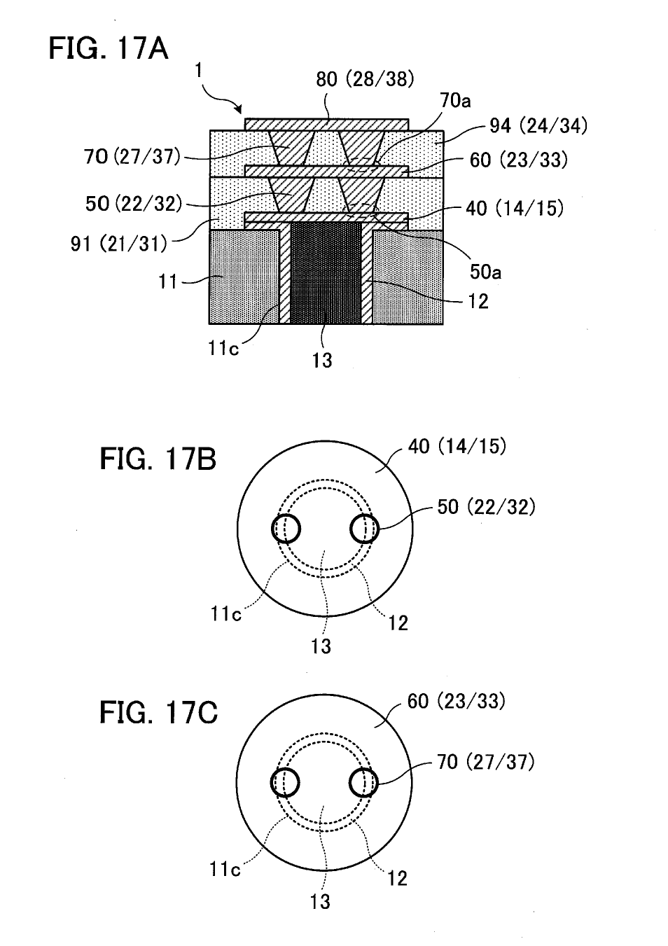

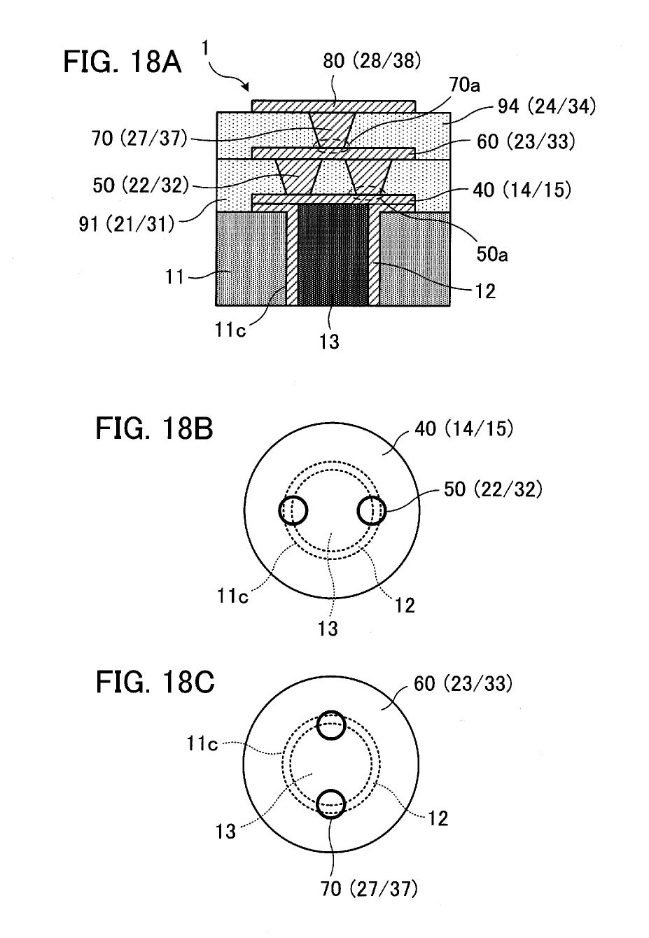

In addition, the vias 27 and the vias 37 in the second layers in the wiring board 1 are arranged in a way illustrated in FIGS. 17A through 17C or FIGS. 18A through 18C.

FIGS. 17A through 17C illustrate an example of the arrangement of vias in upper and lower layers. FIGS. 18A through 18C illustrate an example of the arrangement of vias in upper and lower layers. Each of FIGS. 17A and 18A is a schematic sectional view of via connection portions in two layers. Each of FIGS. 17B and 18B is a schematic plan view of the arrangement of vias on a lower layer side. Each of FIGS. 17C and 18C is a schematic plan view of the arrangement of vias on an upper layer side.

For convenience, a land 40 illustrated in FIGS. 17A, 17B, 18A, and 18B corresponds to the above land 14 or land 15 and vias 50 illustrated in FIGS. 17A, 17B, 18A, and 18B correspond to the above vias 22 or vias 32 in the first layer. Furthermore, a land 60 illustrated in FIGS. 17A, 17C, 18A, and 18C corresponds to the above land 23 or land 33, vias 70 illustrated in FIGS. 17A, 17C, 18A, and 18C correspond to the above vias 27 or vias 37 in the second layer, and a land 80 illustrated in FIGS. 17A and 18A corresponds to the above land 28 or land 38. In addition, an insulating layer 91 illustrated in FIGS. 17A and 18A corresponds to the above insulating layer 21 or insulating layer 31 and an insulating layer 94 illustrated in FIGS. 17A and 18A corresponds to the above insulating layer 24 or insulating layer 34.

Description will now be given with a case where two vias 50 are connected to one land 40 and where two vias 70 are connected to one land 60 as an example.

As illustrated in FIGS. 17A through 17C, for example, the same arrangement method (FIGS. 17B and 17C) is adopted for the two vias 50 in the first layer and the two vias 70 in the second layer to arrange each via 70 in the second layer over each via 50 in the first layer (FIG. 17A). That is to say, the vias 50 (connection regions 50a) in the first layer are arranged over regions of the land 40 extending over the conductor 12 and the resin 13 in the through hole 11c and the vias 70 (connection regions 70a) in the second layer are arranged over regions of the land 60 which are over the vias 50.

With the arrangements illustrated in FIGS. 17A through 17C, a via 50 and a via 70, of the two vias 50 and the two vias 70 connected to lower and upper surfaces, respectively, of the land 60, which are opposite to each other are arranged straight. As a result, a conduction path on which there is no bending point is realized in the direction of the thickness of the wiring board 1.

Furthermore, as illustrated in FIGS. 18A through 18C, different arrangement methods (FIGS. 18B and 18C) may be adopted for the two vias 50 in the first layer and the two vias 70 in the second layer to shift the position of each via 70 in the second layer from the position of each via 50 in the first layer (FIG. 18A). In this case, the two vias 70 in the second layer are arranged over the boundary between the conductor 12 and the resin 13 which is under the land 40. As illustrated in FIGS. 18B and 18C, the arrangement of the two vias 70 in the second layer is obtained by rotating the arrangement of the two vias 50 in the first layer by 90 degrees. That is to say, the vias 50 (connection regions 50a) in the first layer are arranged in regions of land 40 extending over the conductor 12 and the resin 13 in the through hole 11c and the vias 70 (connection regions 70a) in the second layer are arranged over regions of the land 60 which are not over the vias 50 (connection regions 50a).

With the arrangements illustrated in FIGS. 18A through 18C, the two vias 70 in the second layer hold the land 60 formed over the two vias 50 in the first layer which hold the land 40 at positions different from those of the two vias 50. As a result, the land 40 is uniformly held from above and the thermal expansion of the resin 13 in the through hole 11c is controlled.

The case where two vias are connected to one land has been taken as an example. However, three or more vias may be connected to one land. Even in such cases, the same arrangement method or different arrangement methods may be adopted in the same way for vias in the first layer and vias in the second layer. By doing so, the same effect that is described above is obtained.

In the above step described in FIG. 9B (and FIGS. 10 through 12), for example, the position of a spot of a laser beam is set on the basis of the arrangement of the vias 27 and 37 (vias 70) to be formed over the lands 23 and 33 (lands 60), respectively, in order to make the through holes 24c and the through holes 34c. The vias 27 and the vias 37 in the second layers are then formed in the through holes 24c and the through holes 34c, respectively, which are made.

The arrangement of vias in the first and second layers has been described. However, vias in the third and later layers may be arranged in the same way. For example, if the same arrangement method is adopted for vias in the first layer and vias in the second layer, then the same arrangement method is also adopted for vias in the third and later layers. In addition, if different arrangement methods are adopted for vias in the first layer and vias in the second layer, then the same arrangement method is adopted for the vias in the first layer and vias in the third layer and the same arrangement method is adopted for the vias in the second layer and vias in the fourth layer. That is to say, different arrangement methods are adopted for vias in two adjacent layers.

In the above description, for example, the plurality of vias 22 and the plurality of vias 32 are connected to the land 14 and the land 15, respectively, which cover the resin 13 formed in the through hole 11c in the core board 11. In this case, adjacent vias 22 may not be separate from each other in the insulating layer 21 and adjacent vias 32 may not be separate from each other in the insulating layer 31.

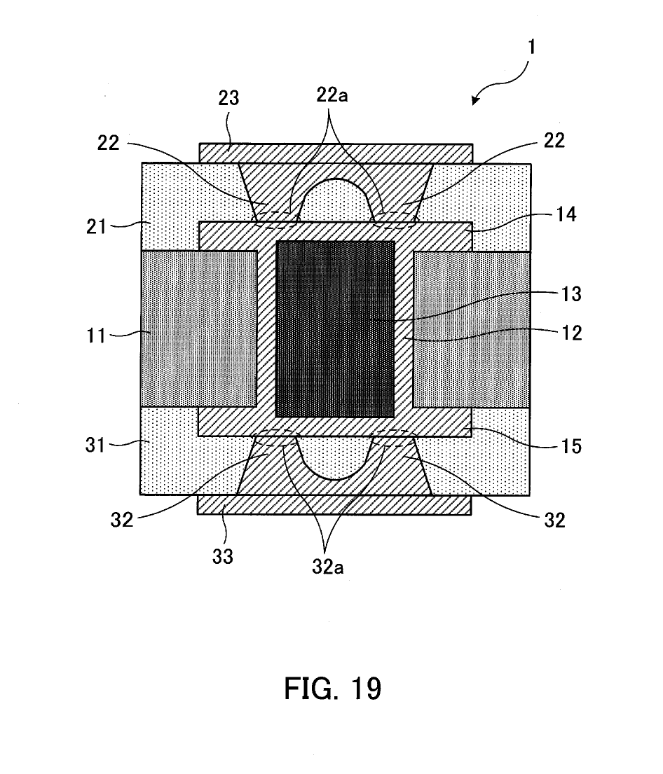

FIG. 19 illustrates another example of a wiring board. FIG. 19 is a fragmentary schematic sectional view of another example of a wiring board.

As illustrated in FIG. 19, the plurality of vias (through holes 21c) in the wiring board 1 connected to the land 14 which covers the resin 13 may partially be connected to one another. Similarly, the plurality of vias (through holes 31c) in the wiring board 1 connected to the land 15 which covers the resin 13 may partially be connected to one another.

Even in this case, the plurality of connection regions 22a are over regions of the land 14 extending over the conductor 12 and the resin 13 in the through hole 11c and the plurality of connection regions 32a are under regions of the land 15 extending under the conductor 12 and the resin 13 in the through hole 11c. Therefore, the land 14 and the land 15 are held by portions corresponding to the plurality of connection regions 22a and the plurality of connection regions 32a. This controls the thermal expansion of the resin 13 to the land 14 side and the land 15 side and therefore prevents a fracture of the land 14 or the land 15.

Similarly, the above plurality of vias 27 (through holes 24c) and plurality of vias 37 (through holes 34c) connected to the land 23 and the land 33, respectively, may partially be connected to one another. A plurality of vias (through holes) which are formed in the wiring board 1 and which are connected to one land may partially be connected in this way to one another.

Furthermore, in the above description through holes, such as the through holes 21c in the insulating layer 21, the through holes 31c in the insulating layer 31, the through holes 24c in the insulating layer 24, and through holes 34c in the insulating layer 34, in which vias are to be formed are made by irradiating the insulating layers with a laser beam. However, through holes may be made by another method. That is to say, through holes may be made by photolithography or etching, depending on the type (material) of an insulating layer in which vias are to be formed. For example, after an insulating layer is formed, a resist mask is formed over the insulating layer and the insulating layer is etched with the resist mask as a mask. By doing so, through holes are made. Alternatively, an insulating layer is formed by the use of a photosensitive material and exposure and development are performed. By doing so, through holes are made. A conductor is formed in through holes made in this way to form vias in an insulating layer.

The wiring board 1 has been described.

Various electronic parts may be mounted on the wiring board 1.

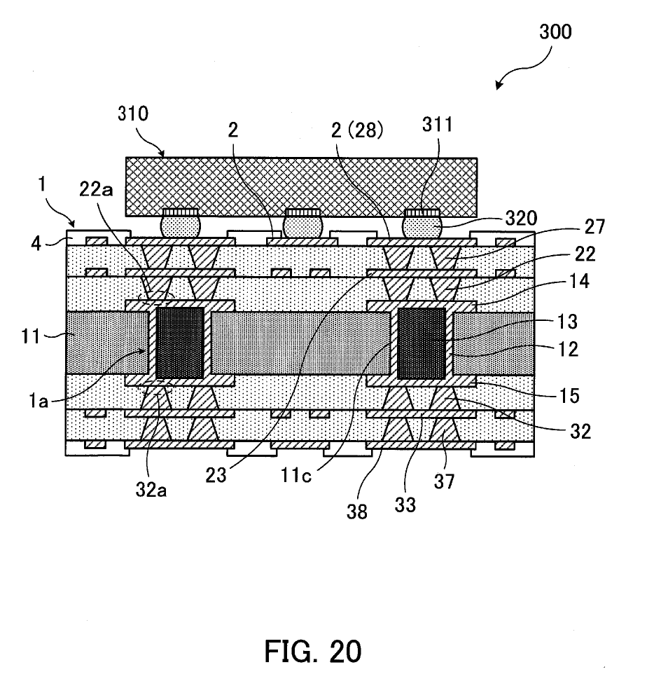

FIG. 20 illustrates an example of an electronic apparatus. FIG. 20 is a fragmentary schematic sectional view of an example of an electronic apparatus.

An electronic apparatus 300 illustrated in FIG. 20 includes the wiring board 1 and an electronic part 310 mounted thereon. A protection film 4, such as solder resist, is formed on the front and back of the wiring board 1. The electronic part 310 mounted on the wiring board 1 is a semiconductor element (semiconductor chip), a semiconductor device (semiconductor package) including a semiconductor element, another wiring board, or the like. An electrode 311 of the electronic part 310 and an electrode 2 of the wiring board 1 are joined by the use of a joining material 320, such as solder, and the electronic part 310 and the wiring board 1 are electrically connected.

In the example of FIG. 20, one electronic part 310 is mounted on the wiring board 1. However, a plurality of electronic parts 310 may be mounted on the wiring board 1. Furthermore, if a semiconductor chip, a semiconductor package, or the like is mounted as the electronic part 310 on the wiring board 1, then a chip part, such as a chip capacitor, may also be mounted.

As stated above, with the wiring board 1 the formation of the plurality of vias 22, the plurality of vias 32, and the like controls the thermal expansion of the resin 13 and prevents a fracture of the land 14 or the land 15 which covers the resin 13. Furthermore, if a plurality of via connection structures 1a are included, an increase in pitch is checked and a deterioration of electrical characteristics, such as a resistance value and an inductance value, is prevented. By using this wiring board 1, the electronic apparatus 300 with high reliability which has good electrical characteristics is realized.

The electronic apparatus 300 may be mounted on another wiring board.

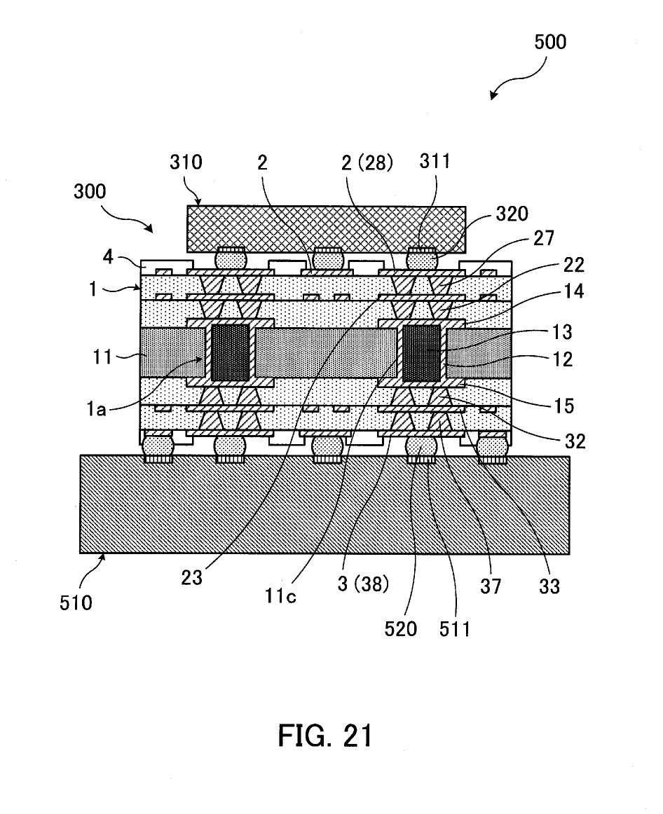

FIG. 21 illustrates another example of an electronic apparatus. FIG. 21 is a fragmentary schematic sectional view of another example of an electronic apparatus.

An electronic apparatus 500 illustrated in FIG. 21 includes a wiring board 510 and the electronic apparatus 300 mounted thereon. As illustrated in FIG. 20, the electronic apparatus 300 includes the wiring board 1 and the electronic part 310 mounted thereon. An electrode of the wiring board 1 included in the electronic apparatus 300 and an electrode 511 of the wiring board 510 are joined by the use of a joining material 520, such as solder, and the electronic apparatus 300 and the wiring board 510 are electrically connected.

By using the wiring board 1, the electronic apparatus 500 with high reliability which includes the electronic apparatus 300 and which has good electrical characteristics is realized.

The disclosed technique prevents a fracture of a conductor portion formed over a resin portion in a through hole in an insulating portion and realizes a wiring board with high reliability. The disclosed technique also realizes an electronic apparatus with high reliability including such a wiring board.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A wiring board comprising:
a first insulating portion;
a first through hole made in the first insulating portion;
a first conductor portion formed on an inner wall of the first through hole;
a first resin portion formed inside the first conductor portion in the first through hole;
a second conductor portion formed over the first conductor portion and the first resin portion;
a second insulating portion formed over the second conductor portion; and
a third conductor portion formed in the second insulating portion and connected to a plurality of first regions of the second conductor portion extending over the first conductor portion and the first resin portion.

2. The wiring board according to claim 1, wherein the third conductor portion includes a plurality of vias connected to the plurality of first regions.

3. The wiring board according to claim 1, wherein the plurality of first regions are situated at constant intervals.

4. The wiring board according to claim 1 further comprising:
a fourth conductor portion formed over the third conductor portion;
a third insulating portion formed over the fourth conductor portion; and
a fifth conductor portion formed in the third insulating portion and connected to a plurality of second regions of the fourth conductor portion situated over the plurality of first regions.

5. The wiring board according to claim 1 further comprising:
a fourth conductor portion formed over the third conductor portion;
a third insulating portion formed over the fourth conductor portion; and
a fifth conductor portion formed in the third insulating portion and connected to a plurality of second regions of the fourth conductor portion situated in regions different from regions over the plurality of first regions.

6. The wiring board according to claim 1 further comprising:
a second through hole made in the first insulating portion at a position different from a position at which the first through hole is made;
a sixth conductor portion formed on an inner wall of the second through hole;
a second resin portion formed inside the sixth conductor portion in the second through hole;
a seventh conductor portion formed over the sixth conductor portion and the second resin portion, the second insulating portion being formed over the second conductor portion and the seventh conductor portion; and
an eighth conductor portion formed in the second insulating portion and connected to a plurality of third regions of the seventh conductor portion extending over the sixth conductor portion and the second resin portion, an arrangement of the plurality of third regions being obtained by rotating an arrangement of the plurality of first regions by an angle of 90 degrees or less from above.

7. The wiring board according to claim 1 further comprising:
a ninth conductor portion formed under the first conductor portion and the first resin portion;
a fourth insulating portion formed under the ninth conductor portion; and
a tenth conductor portion formed in the fourth insulating portion and connected to a plurality of fourth regions of the ninth conductor portion extending under the first conductor portion and the first resin portion.

8. A wiring board fabrication method comprising:
making a first through hole in a first insulating portion;
forming a first conductor portion on an inner wall of the first through hole;
forming a first resin portion inside the first conductor portion in the first through hole;
forming a second conductor portion over the first conductor portion and the first resin portion;
forming a second insulating portion over the second conductor portion; and
forming in the second insulating portion a third conductor portion connected to a plurality of first regions of the second conductor portion extending over the first conductor portion and the first resin portion.

9. The wiring board fabrication method according to claim 8, wherein the forming the third conductor portion in the second insulating portion includes:
making in the formed second insulating portion a third through hole leading to the plurality of first regions; and
forming the third conductor portion in the made third through hole.

10. The wiring board fabrication method according to claim 8, wherein the forming the third conductor portion in the second insulating portion includes:
setting positions of the plurality of first regions by the use of information regarding thickness of the first conductor portion from the inner wall of the first through hole; and
forming the third conductor portion at the set positions of the plurality of first regions.

11. The wiring board fabrication method according to claim 10, wherein the information is a design value of the thickness of the first conductor portion from the inner wall of the first through hole.

12. The wiring board fabrication method according to claim 10 further comprising, after the forming the first conductor portion, measuring the thickness of the formed first conductor portion from the inner wall of the first through hole, wherein the information is a measured value obtained by measuring the thickness.

13. An electronic apparatus comprising:
a wiring board; and
an electronic part mounted on the wiring board,
wherein the wiring board includes:
a first insulating portion;
a first through hole made in the first insulating portion;
a first conductor portion formed on an inner wall of the first through hole;
a first resin portion formed inside the first conductor portion in the first through hole;
a second conductor portion formed over the first conductor portion and the first resin portion;
a second insulating portion formed over the second conductor portion; and
a third conductor portion formed in the second insulating portion and connected to a plurality of first regions of the second conductor portion extending over the first conductor portion and the first resin portion.
